(19) United States
(12) Patent Application Publication
(10) Pub. No.: US 2025/0369106 A1
(43) Pub. Date: Dec. 4, 2025

(54) TRANSITION-METAL CHALCOGENIDE WAFER, PREPARATION METHOD THEREFOR, AND DEVICE THEREOF

(71) Applicant: PEKING UNIVERSITY, Beijing (CN)

(72) Inventors: Kaihui LIU, Beijing (CN); Can LIU, Beijing (CN); Enge WANG, Beijing (CN); Guodong XUE, Beijing (CN)

(73) Assignee: PEKING UNIVERSITY, Beijing (CN)

(21) Appl. No.: 18/859,527

(22) PCT Filed: Jun. 29, 2023
(86) PCT No.: PCT/CN2023/104236

§ 371 Date: Oct. 23, 2024

(30) Foreign Application Priority Data
Jun. 9, 2023 (CN) 202310687180.4

(51) Int. Cl. C23C 16/448; C23C 16/30; C23C 16/458

(52) U.S. Cl. CPC C23C 16/448; C23C 16/305; C23C 16/4583

(57) ABSTRACT

The present disclosure relates to a transition-metal chalcogenide wafer, preparation method therefor, and device thereof. The preparation method includes: S1, assembling the growth modules; and S2, vertically stacking the assembled growth modules to obtain the combined growth module; placing the combined growth module in a container; heating up to a preset temperature under an inert gas protective atmosphere; and performing a chemical vapor deposition to obtain the wafer.

### CROSS-REFERENCE TO RELATED APPLICATION

The present disclosure claims priority to Chinese patent Application No. 202310687180.4, filed with the Chinese Patent Office on Jun. 9, 2023, entitled “TRANSITION-METAL CHALCOGENIDE WAFER, PREPARATION METHOD THEREFOR, AND DEVICE THEREOF”, the entire contents of which are incorporated herein by reference.

### TECHNICAL FIELD

The present disclosure relates to the technical field of two-dimensional materials, and particularly relates to a transition-metal chalcogenide wafer, a preparation method therefor, and a device thereof.

### BACKGROUND ART

Two-dimensional transition-metal chalcogenides have excellent physical and chemical properties, such as atomic layer thickness, high carrier mobility, and ultrafast charge transfer, which show broad promising prospects in fields of the ultra-scaled field effect transistor. wearable electronics, and flexible displays, etc. Currently, the chemical vapor deposition technology is considered to be the most effective method for preparing high-quality wafer-scale two-dimensional transition-metal chalcogenides. However, limited by the poor diffusion ability of the growth precursor, the large-size transition-metal chalcogenide wafer cannot be prepared by traditional preparation technologies, wherein the mainstream wafer size is smaller than 4 inches, which cannot be compatible with the industrial semiconductor process line. Further, the traditional preparation technology needs to be provided with multiple reaction heating zones and auxiliary diffusion equipment, which greatly limits the preparation efficiency for the transition-metal chalcogenide wafer. The preparation capability is usually one piece per batch, which cannot meet the material requirements in the rapidly developed two-dimensional semiconductor technology.

### SUMMARY

In order to solve the technical problems in the prior art that the growth precursor has a poor diffusion ability, and thus cannot realize the preparation of large-size wafers, and the preparation efficiency is low, the present disclosure provides a device for preparing the above wafer, wherein the device can prepare the transition-metal chalcogenide wafers in different material types and their various derivatives in batch quantity (including, but not limited to multi-component alloys, Janus alloys, heterojunction structures).

Some embodiments of the present disclosure provide a device for preparing the above wafer, thereby at least solving the technical problems in the prior art.

In some embodiments, the device for preparing the above wafer can include:
a slot assembly, wherein the slot assembly is provided with a plurality of slot units, wherein a single slot unit is sequentially provided with a first slot, a second slot, and a third slot from top to bottom, and the first slot, the second slot and the third slot are arranged at intervals from each other; and
a support assembly, wherein the support assembly is provided with through holes adapted to the slot assembly; and the slot assembly is arranged in the through hole; and a plurality of through holes are provided.

In some embodiments, the spacing between the first slot, the second slot and the third slot can be adjusted according to a ratio of a transition-metal source/a chalcogenide source required for a preparation material.

In some embodiments, three through holes can be provided, wherein each of the three through holes is snapped therein with the slot assembly, and the three through holes are distributed triangularly.

In some embodiments, a width of the first slot and a width of the second slot may be the same or different; and a width of the third slot is larger than the width of the first slot, and/or the width of the third slot is larger than the width of the second slot.

The present disclosure further provides a preparation method for the transition-metal chalcogenide wafer. The method adopts a “face-to-face” local element supply technology and selects a precursor with high reactive activity, so as to effectively solve the problem in the traditional mode that the supply for the source by the “point-to-face” diffusion is not uniform. The precursor element supply method in the present disclosure can greatly improve the size of the wafer prepared, wherein the size of a single transition-metal chalcogenide wafer is expanded to 12 inches and above, which achieves a level of being compatible with industrial semiconductor processes; and the batch production of multiple wafers can be realized through continuously stacking the growth modules.

Some other embodiments of the present disclosure provide a preparation method for the transition-metal chalcogenide wafer, thereby at least solving the technical problems to be solved by the present disclosure.

In some embodiments, the preparation method for the transition-metal chalcogenide wafer can include:
S1, placing a growth substrate, a platy substrate with a transition-metal precursor, and a supply source of chalcogenide elements into a first slot, a second slot, and a third slot of the slot unit respectively to obtain an assembled growth module; and
S2, stacking a plurality of growth modules assembled in step S1 to obtain a combined growth module; placing the combined growth module in a container; heating up to a preset temperature under an inert gas protective atmosphere; and performing a chemical vapor deposition to obtain a transition-metal chalcogenide wafer.

In some embodiments, the step of preparing the substrate with the transition-metal precursor can include: dispersing the liquid transition-metal source on the substrate by spin coating, and then performing a drying process at 60-100° C.; or taking a platy solid transition-metal source as the substrate with the transition-metal precursor.

In some embodiments, the growth substrate can include any one of an Al₂O₃ wafer, a fused silica wafer, a SiO₂/Si wafer, and a gold foil wafer.

In some embodiments, the transition metal can include any one of molybdenum, tungsten, niobium, and rhenium.

Optionally, the liquid transition-metal source can include any one of sodium molybdate, sodium tungstate, and ammonium molybdate.

Optionally, the solid transition-metal source can include a transition-metal target or a transition-metal foil wafer.

In some embodiments, the transition-metal target includes any one of molybdenum oxide, tungsten oxide, and niobium oxide; and the transition-metal foil wafer can include any one of molybdenum foil, tungsten foil, and niobium foil.

In some embodiments, the substrate can include any one of a SiO₂/Si substrate, an Al₂O₃ substrate, a fused silica substrate, a gold substrate, and a mica substrate with equally spaced holes.

Optionally, the base can have a diameter of 1-450 mm.

In some embodiments, the supply source of chalcogenide elements can include an elementary chalcogenide substance or a chalcogenide wafer.

Optionally, the elementary chalcogenide substance includes any one of sulfur powder, selenium powder, and tellurium powder; and the chalcogenide wafer includes a wafer made by pressing one or more of zinc sulfide, zinc selenide, zinc telluride, and tellurium oxide.

In some embodiments, the step S2 can include: placing the combined growth module on a high-temperature resistant plate, and putting them into a tubular container together; vacuumizing the tubular container until a pressure inside the container is 0.1-1 Pa; injecting an inert gas and maintaining a pressure inside the container at 50-300 Pa; and heating to 500-1100° C. and preserving a temperature for 20-60 min.

Optionally, a heating rate is 20-100° C./min.

Optionally, the high-temperature resistant plate includes a quartz plate or an alumina plate.

Optionally, the inert gas serves as a carrier gas at the same time.

Optionally, the inert gas includes argon or nitrogen.

In some embodiments, the number of the growth modules stacked can be 1-1000 in the step S2.

In some embodiments, the preparation method can further include a pretreatment for the substrate before the step S1, wherein the pretreatment includes any one of plasma treatment, potassium hydroxide solution treatment and piranha solution treatment.

In some embodiments, after the step S2, a heating process can be turned off; a flow rate of a protective gas is maintained to be unchanged; and a system is cooled to a room temperature, so as to obtain wafer-scale transition-metal chalcogenides deposited on the growth substrate in batch quantity.

The present disclosure further provides a transition-metal chalcogenide wafer made by the above preparation method. The wafer is of the uniform monolayer with a high crystallinity and low defect density.

Some other embodiments of the present disclosure provide a transition-metal chalcogenide wafer made by the above preparation method, thereby at least solving the technical problems to be solved by the present disclosure.

### BRIEF DESCRIPTION OF DRAWINGS

In order to more clearly illustrate the technical solutions of the examples of the present disclosure, the drawings to be used in the examples will be briefly introduced below. It should be understood that the following drawings only show certain examples of the present disclosure, and therefore should not be regarded as a limitation of the scope. Other relevant drawings may be obtained from these drawings by a person of ordinary skill in the art without inventive efforts.

FIG. 1 shows a structure schematic diagram of a wafer preparation device of the examples of the present disclosure;

FIG. 2 shows a structure schematic diagram of a slot assembly of the examples of the present disclosure;

FIG. 3 shows a top view of a slot assembly of the examples of the present disclosure;

FIG. 4 shows a top view of a wafer preparation device of the examples of the present disclosure;

FIG. 5 shows a sectional diagram at A-A in FIG. 4;

FIG. 6 shows a picture of real product of 2-inch single-layer MoS₂ in Example 1 of the present disclosure;

FIG. 7 shows a STEM image of 2-inch single-layer MoS₂ in Example 1 of the present disclosure; and

FIG. 8 shows a picture of real product of 12-inch single-layer MoS₂ in Example 2 of the present disclosure.

Reference numbers: 100—support assembly; 200—slot assembly; 201—first slot; 202—second slot; and 203—third slot.

### DETAILED DESCRIPTION OF EMBODIMENTS

In order to make the purpose, technical solutions, and advantages of the examples of the present disclosure clearer, the technical solutions in the examples of the present disclosure will be described clearly and completely as follows. Where specific conditions are not indicated in the examples, they shall be performed based on the usual conditions or those recommended by manufacturers. The reagents or instruments used without indication of the manufacturers are conventional products that can be purchased commercially.

The features and performance of the present disclosure are further described in detail below in connection with the examples.

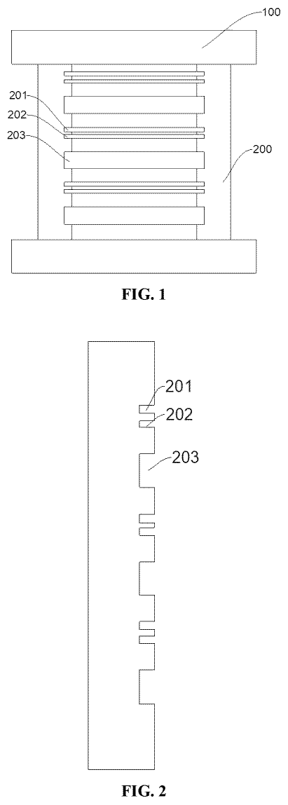

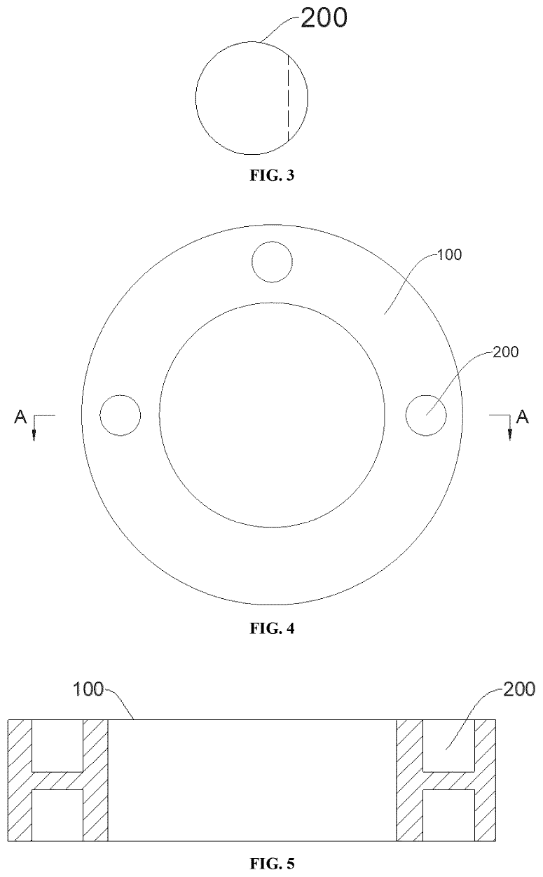

FIG. 1 shows a structure schematic diagram of a wafer preparation device of the examples of the present disclosure; FIG. 2 shows a structure schematic diagram of a slot assembly 200 of the examples of the present disclosure; FIG. 3 shows a top view of a slot assembly 200 of the examples of the present disclosure; FIG. 4 shows a top view of a wafer preparation device of the examples of the present disclosure; and FIG. 5 shows a sectional diagram at A-A in FIG. 4. Referring to FIG. 1-FIG. 5, the examples of the present disclosure provide a device for preparing the wafer, wherein the device can include:
a slot assembly 200, wherein the slot assembly 200 is provided with a plurality of slot units, wherein a single slot unit is sequentially provided with a first slot 201, a second slot 202, and a third slot 203 from top to bottom, and the first slot 201, the second slot 202, and the third slot 203 are arranged at intervals from each other; and
a support assembly 100, wherein the support assembly 100 is provided with through holes (not shown in the figures) adapted to the slot assembly 200; and the slot assembly 200 is arranged in the through hole; and a plurality of through holes are provided.

During use, the first slot 201, the second slot 202, and the third slot 203 together compose a slot unit, and a plurality of slot units are arranged side by side, wherein the spacing between the first slot 201, the second slot 202, and the third slot 203 can be accurately adjusted according to a ratio of transition-metal source/chalcogenide source required for the preparation material. For example, reducing the spacing between the first slot 201 and the second slot 202 can effectively improve the concentration of the transition-metal source, and increasing the spacing between the second slot 202 and the third slot 203 can effectively reduce the concentration of the chalcogenide source, which is not limited herein by the present disclosure.

In this process, the slot assembly 200 is snapped into the through hole in the support assembly 100, wherein two support assemblies 100 are provided, and arranged on two ends of the slot assembly 200, to facilitate fixing the slot assembly 200 to the support assembly 100. Exemplarily, in the present disclosure, the support assembly 100 is provided with three through holes, wherein each of the three through holes is snapped therein with the slot assembly 200, and the three through holes are distributed triangularly. In this way, the materials (such as the wafer, substrate, and base) in each slot can be fixedly placed into their corresponding slots, and are not easy to fall off.

The number of through holes can be increased or decreased according to the actual situation, which is not limited herein by the present disclosure.

The device can increase the number of the prepared wafers by increasing the number of slot units, so that the device can prepare the transition-metal chalcogenide wafers in different material types and their various derivatives (including, but not limited to multi-component alloys, Janus structures, heterojunction structures) in batch quantity. The number of slot units is 1-1000. Exemplarily, the number of slot units includes, but is not limited to 1, 20, 40, 60, 80, 100, 200, 400, 600, 650, 720, 800, 850, 900, 920, and 1000.

In some examples, a width of the first slot 201 and a width of the second slot 202 are the same or different; and a width of the third slot 203 is larger than the width of the first slot 201, and the width of the third slot 203 is larger than the width of the second slot 202.

The third slot 203 has the largest width among the three slots, and is used to place a supply source of chalcogenide elements. The first slot 201 may have the same width or different width with the second slot 202, and they are used to place a growth substrate and a substrate with a transition-metal precursor respectively. As an example, the widths of the first slot 201 and the second slot 202 are both 1 mm, and the width of the third slot 203 is 5 mm.

How to prepare the transition-metal chalcogenide wafer by using the above device will be introduced below.

The preparation method is as follows:
(1) placing the growth substrate, the platy substrate with the transition-metal precursor, and the supply source of chalcogenide elements into the first slot 201, the second slot 202, and the third slot 203 of the slot units respectively to obtain assembled growth module; and
(2) stacking a plurality of growth modules assembled in step (1) to obtain a combined growth module; placing the combined growth module in a container; heating up to a preset temperature under an inert gas protective atmosphere; and performing a chemical vapor deposition to obtain the transition-metal chalcogenide wafer.

In the present disclosure, the transition metal elements and the chalcogenide elements are supplied in a “face-to-face” manner, which is very important for preparing the super-size (>4 inches) wafer. Additionally, by adopting the “face-to-face” local element supply technology and selecting the precursor with high reactive activity, the problem in the traditional mode that the supply for the growth source by the “point-to-face” diffusion is not uniform can be effectively solved. The precursor element supply method in the present disclosure can greatly expand the size of the wafer prepared, wherein the size of a single transition-metal chalcogenide wafer is expanded to 12 inches and above, which achieves a level of being compatible with industrial semiconductor processes. Further, the “face-to-face” manner in the present disclosure can greatly reduce the volume (reducing from the overall furnace to a few cubic centimeters) of the single module prepared, thereby ultimately realizing the simultaneous production for multiple wafers in a single batch.

In some examples, the step of preparing the substrate with the transition-metal precursor includes: applying a liquid transition-metal source on the substrate by means of spin coating, and then performing a drying process at 60-100° C.; or taking a platy solid transition-metal source as the substrate with the transition-metal precursor. The temperature of the drying process can be adjusted according to actual situations, and is not limited by the present disclosure.

In the above technical solution, the metal source solution has fluidity and plasticity, to be easily processed and operated in various shapes, such as spin coating and pouring, which is more operable. The metal source solution can be mixed well with other substances, which is convenient for preparing alloys or modifying the material, and is good for mixing. The metal source solution can be adjusted in a certain temperature range, to adapt to the different process requirements, which is good for temperature adjustment. The solid metal source exists in forms of bulk, powder, or other forms, and has a larger supply source, which is suitable for mass production; and at the same time, the solid metal source usually has better chemical stability and thermal stability, and is not easy to change or oxidate. Compared to the metal source solution, the processing and shape adjustment for the solid metal source are more difficult, and it needs to adopt processes such as fusion and pressing.

In some examples, the growth base includes any one of an Al₂O₃ wafer, a fused silica wafer. a SiO₂/Si wafer, and a gold foil wafer.

In some examples, the transition metal includes any one of molybdenum, tungsten, niobium, and rhenium; the liquid transition-metal source includes any one of sodium molybdate, sodium tungstate, and ammonium molybdate; and the solid transition-metal source includes a transition-metal target or a transition-metal foil wafer.

The transition-metal target includes any one of molybdenum oxide, tungsten oxide, and niobium oxide; and the transition-metal foil wafer includes any one of molybdenum foil, tungsten foil, and niobium foil.

In some examples, the substrate includes any one of a SiO₂/Si substrate, an Al₂O₃ substrate, a fused silica substrate, a gold substrate, and a mica substrate with equally spaced holes.

In some examples, the diameter of the substrate is 1-450 mm. The sizes of the above preparation device, substrate, and base can be customized on demand, and the sizes of the diameters are 1-450 mm. As an example, they include, but are not limited to 1 mm, 10 mm, 30 mm, 60 mm. 80 mm, 100 mm, 140 mm, 180 mm, 200 mm, 230 mm, 260 mm, 290 mm, 320 mm, 380 mm, 400 mm, 420 mm, and 450 mm.

In some examples, the supply source of chalcogenide elements includes an elementary chalcogenide substance or a chalcogenide wafer, wherein the elementary chalcogenide substance includes any one of sulfur powder, selenium powder, and tellurium powder, and the chalcogenide wafer includes the wafer made by pressing one or more of zinc sulfide, zinc selenide, zinc telluride, and tellurium oxide.

In some examples, step (2) includes: placing the combined growth module on the high-temperature resistant plate, and putting them into the tubular container together; vacuumizing the tubular container until the gas pressure inside the container is 0.1-1 Pa; injecting the inert gas and maintaining the pressure inside the container at 50-300 Pa; and heating to 500-1100° C. at the heating rate of 20-100° C./min, and preserving the temperature for 20-60 min.

In the above technical solution, the high-temperature resistant plate includes a quartz plate or an alumina plate; the inert gas includes argon or nitrogen; and the inert gas serves as a carrier gas at the same time.

In some examples, the number of growth modules stacked is 1-1000. In this process, one wafer is grown from one growth module, and the batch production of wafers can be realized by stacking multiple growth modules for reaction. The growth source in the present disclosure is supplied in the module by means of a “face-to-face” manner, which is no longer limited by the diffusion of sources, and the batch production of multiple wafers can be realized by continuously stacking. As an example, the number of the growth modules stacked includes, but is not limited to 1, 20, 40, 60, 80, 100, 200, 400, 600, 650, 720, 800, 850, 900, 920, and 1000. The number of growth modules included in the overall device can be customized on actual demands, and it is 1-1000 pieces per batch.

In some examples, the method further includes a pretreatment for the substrate before step (1), wherein the pretreatment includes any one of plasma treatment, potassium hydroxide solution treatment and piranha solution treatment. The purpose of the pretreatment is to clean the substrate. As an example, the pretreatment is to clean for 1-10 min by using plasma of 90 W. or soak for 5-10 min by using one of the potassium hydroxide solution and piranha solution.

In some examples, after finishing step (2), the heating process is turned off; a flow rate of protective gas is maintained to be unchanged (the range is 10-1000 sccm); and the system is cooled to a room temperature, to obtain the wafer-scale transition-metal chalcogenides deposited on the growth base in batch quantity. The gas flow rate depends on the device used and the growth material, and exemplarily, the gas flow rate includes, but is not limited to 10 sccm1, 60 sccm, 120 sccm, 200 sccm, 300 sccm, 400 sccm, 500 sccm, 600 sccm, 700 sccm, 800 sccm, 900 sccm, and 1000 sccm.

### Example 1

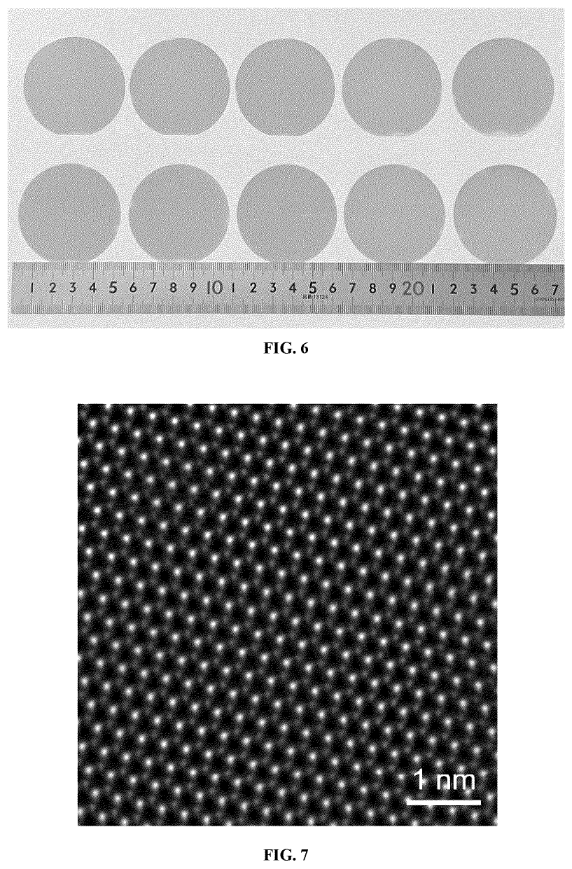

The example prepared high-quality 2-inch wafer-scale MoS₂ in batch quantity according to the preparation device and method provided by the present disclosure, wherein the specific steps were as follows.
(1) A 2-inch Al₂O₃ wafer was taken as the growth substrate and was placed in the first slot 201 of the slot unit.
(2) Oxygen plasma was used to pretreat the fused silica substrate to improve the hydrophilicity of the substrate surface; 0.25 g of sodium molybdate (purchased from Aladdin's Reagent) was weighed, and dissolved in 40 mL of deionized water; the Na₂MoO₄ solution was then uniformly coated onto a first surface of the fused silica substrate through spin coating; and then they were placed on a heating plate at 80° C. for drying, and then placed into the second slot 202 of the slot unit.
(3) A zinc sulfide wafer was taken as a supply source of chalcogenide element, and a 2-inch zinc sulfide wafer was placed in the third slot 203 of the slot unit to form one growth module, wherein the growth module from top to bottom included an Al₂O₃ wafer, a substrate with sodium molybdate, and a zinc sulfide wafer, and slots were arranged at intervals, wherein the silica substrate surface coated with Na₂MoO₄ was arranged opposite to the Al₂O₃ wafer.
(4) The steps (1)-(3) were repeated. The Al₂O₃ wafer, the silica substrate with sodium molybdate, and the zinc sulfide wafer were placed into other slot units of the device; and the assembled device with 10 slot units was placed on the quartz plate and then placed into a tube furnace for the batch preparation.
(5) The tube furnace was vacuumized. When the gas pressure inside the tube furnace reached 0.1 Pa, 500 sccm argon was injected, and the pressure in the tube was maintained at 50 Pa; the heating rate was controlled at 18° C./min, and the temperature was set at 780° C., and then the temperature was preserved for 40 min for growth.
(6) After the growth, the heating process was turned off; the argon flow rate (500 sccm) was maintained unchanged; and the system was cooled to room temperature to obtain wafer-scale transition-metal chalcogenide samples grown on the AL₂O₃ substrates in batch quantity, as shown in FIG. 6. It can be seen from FIG. 6 that the example of the present disclosure can obtain 10 pieces of 2-inch high-quality MoS₂ in a single batch, and the wafers are uniform and free of defects. FIG. 7 shows a STEM image of the above wafer sample. It can be seen from FIG. 7 that the wafers have complete hexagonal honeycomb lattice structures, and have high crystallinity.

### Example 2

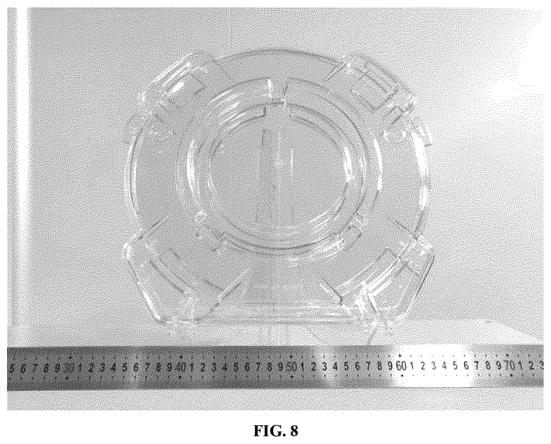

The example prepared high-quality 12-inch wafer-scale MoS₂ in batch quantity according to the preparation device and method provided by the present disclosure, wherein the specific steps were as follows.
(1) A 12-inch fused silica wafer was taken as the growth substrate and placed in the first slot 201 of the slot unit.
(2) The oxygen plasma was used to pretreat the fused silica substrate to improve the hydrophilicity of the substrate surface; 2 g of sodium molybdate (purchased from Aladdin's Reagent) was weighed, and dissolved in 40 mL of deionized water; the Na₂MoO₄ solution was uniformly coated onto the first surface of the fused silica substrate through spin coating next; and then they were placed on the heating plate at 80° C. for drying, and then placed into the second slot 202 of the slot unit.
(3) The zinc sulfide wafer was taken as the supply source of chalcogenide element, and the 12-inch zinc sulfide wafer was placed in the third slot 203 of the slot unit to form one growth module, wherein the growth module from top to bottom included a fused silica wafer, the substrate with sodium molybdate, and the zinc sulfide wafer, and the slots were arranged at intervals, wherein the silica substrate surface coated with Na₂MoO₄ was arranged opposite to the fused silica wafer.
(4) The steps (1)-(3) were repeated. The fused silica wafer, the silica substrate with sodium molybdate, and the zinc sulfide wafer were placed into the other slot units of the device; and the assembled device with 3 slot units was placed on the quartz plate and then placed into the tube furnace for the batch preparation.
(5) The tube furnace was vacuumized. When the gas pressure inside the tube furnace reached 0.1 Pa, nitrogen was injected, and the pressure in the tube was maintained at 300 Pa; the heating rate was controlled at 18° C./min, and the temperature was heated to 850° C.; and then the temperature was preserved for 40 min for growth.
(6) After the growth, the heating process was turned off; the nitrogen flow rate (1000 sccm) was maintained unchanged: and the system was cooled to room temperature to obtain wafer-scale transition-metal chalcogenide samples grown on the fused silica substrate in batch quantity. FIG. 8 shows the 12-inch wafer-level MoS₂ grown on the fused silica substrate in batch quantity, and the wafers are uniform and free of defects.

### Example 3

The example prepared high-quality wafer-scale MoS₂ₓS₂₍₁₋ₓ₎ alloys in batch quantity according to the preparation device and method provided by the present disclosure, wherein the specific steps were as follows.

(1) The 2-inch alumina wafer was taken as the growth substrate and was placed in the first slot 201 of the slot unit.
(2) The oxygen plasma was used to pretreat the fused silica substrate to improve the hydrophilicity of the surface; 0.25 g of sodium molybdate (purchased from Aladdin's Reagent) was weighed, and dissolved in 40 mL of deionized water; the Na₂MoO₄ solution was uniformly coated onto the first surface of the fused silica substrate through spin coating next; and then they were placed on the heating plate at 80° C. for drying, and then placed into the second slot 202 of the slot unit.
(3) A zinc sulfide/zinc selenide pressed wafer was taken as the supply source of chalcogenide element, and a 2-inch zinc sulfide/zinc selenide pressed wafer was placed in the third slot 203 of the slot unit to form one growth module, wherein the growth module from top to bottom included an Al₂O₃ wafer, a substrate with sodium molybdate, and a zinc sulfide/zinc selenide pressed wafer, and the slots were arranged at intervals, wherein the silica substrate surface coated with Na₂MoO₄ was arranged opposite to the Al₂O₃ wafer.
(4) The steps (1)-(3) were repeated. The Al₂O₃ wafer, the silica substrate with sodium molybdate, and the zinc sulfide wafer were placed into the other slot units of the device; and the assembled device with 5 slot units was placed on the quartz plate and then placed into the tube furnace for the batch preparation.
(5) The tube furnace was vacuumizing. When the gas pressure inside the tube furnace reached 0.1 Pa, argon was injected, and the pressure in the tube was maintained at 300 Pa; the heating rate was controlled at 18° C./min, and the temperature was heated to 850° C., and then the temperature was preserved for 40 min for growth.
(6) After the growth, the heating process was turned off; the argon flow rate (100 sccm) was maintained unchanged; and the system was cooled to room temperature to obtain the wafer-scale transition-metal chalcogenide samples grown on the Al₂O₃ substrates in batch quantity.

The present disclosure can prepare the wafer-scale alloys with different ratios in batch quantity by controlling different temperatures. The samples obtained are transition-metal chalcogenide alloys with different ratios, wherein the chalcogenide elements are of different ratios and different band gaps, which realizes adjustable band gaps for the two-dimensional materials.

The examples described above are partial examples of the present disclosure, and not all examples. The detailed description of examples of the present disclosure is not intended to limit the scope of the present disclosure for which protection is claimed, but only represents selected examples of the present disclosure. Based on the examples in the present disclosure, all other examples obtained by a person of ordinary skill in the art without inventive efforts, all fall within the scope of protection of the present disclosure.

### Industrial Applicability

The present disclosure provides a transition-metal chalcogenide wafer, preparation method therefor, and device thereof, which belong to the technical field of two-dimensional materials. The preparation method includes: S1, assembling the growth modules; and S2, vertically stacking the assembled growth modules to obtain the combined growth module; placing the combined growth module in the container; heating up to the preset temperature under the inert gas protective atmosphere; and performing the chemical vapor deposition to obtain the wafer. The method adopts the “face-to-face” local element supply technology and selects the precursor with high reactive activity, to effectively solve the problem in the traditional mode that the supply for the growth source by the “point-to-face” diffusion is not uniform. The precursor element supply method in the present disclosure can greatly expand the size of the wafer prepared, wherein the size of the single transition-metal chalcogenide wafer is expanded to 12 inches and above, which achieves the level of being compatible with industrial semiconductor processes; and the batch production of multiple wafers can be realized through continuously stacking growth modules.

Additionally, it can be understood that the transition-metal chalcogenide wafers, preparation method therefor, and device thereof in the present disclosure are reproducible, and can be applied in multiple industrial applications. For example, the transition-metal chalcogenide wafer, preparation method therefor, and device thereof of the present disclosure can be applied in the technical field of two-dimensional materials.

1. A device for preparing a transition-metal chalcogenide wafer, comprising
a slot assembly, wherein the slot assembly is provided with a plurality of slot units, wherein a single slot unit is sequentially provided with a first slot, a second slot, and a third slot from top to bottom, and the first slot, the second slot and the third slot are arranged at intervals from each other; and
a support assembly, wherein the support assembly is provided with through holes adapted to the slot assembly; the slot assembly is arranged in the through hole; and a plurality of through holes are provided.

2. The device according to claim 1, wherein a spacing between the first slot, the second slot and the third slot is adjusted according to a ratio of a transition-metal source/a chalcogenide source required for a preparation material.

3. The device according to claim 1, wherein three through holes are provided, wherein each of the three through holes is snapped therein with the slot assembly, and the three through holes are distributed triangularly.

4. The device according to claim 1, wherein a width of the first slot and a width of the second slot are the same or different; and a width of the third slot is larger than the width of the first slot, and/or the width of the third slot is larger than the width of the second slot.

5. A preparation method for a transition-metal chalcogenide wafer, wherein the transition-metal chalcogenide wafer is prepared by the device according to claim 4, and the preparation method comprises:
S1, placing a growth substrate, a platy substrate with a transition-metal precursor, and a supply source of chalcogenide elements into a first slot, a second slot, and a third slot of a slot unit respectively to obtain an assembled growth module; and
S2, stacking a plurality of growth modules assembled in step S1 to obtain a combined growth module; placing the combined growth module in a container; heating up to a preset temperature under an inert gas protective atmosphere; and performing a chemical vapor deposition to obtain the wafer.

6. The preparation method according to claim 5, wherein a step of preparing the substrate with the transition-metal precursor comprises: applying a liquid transition-metal source on the substrate by spin coating, and then performing a drying process at 60-100° C.; or taking a platy solid transition-metal source as the substrate with the transition-metal precursor.

7. The preparation method according to claim 6, wherein the growth base comprises any one of an Al₂O₃ wafer, a fused silica wafer, a SiO₂/Si wafer, and a gold foil wafer.

8. The preparation method according to claim 6, wherein a transition metal comprises any one of molybdenum, tungsten, niobium, and rhenium, wherein
optionally, the liquid transition-metal source comprises any one of sodium molybdate, sodium tungstate, and ammonium molybdate; and
optionally, the solid transition-metal source comprises a transition-metal target or a transition-metal foil wafer.

9. The preparation method according to claim 8, wherein the transition-metal target comprises any one of molybdenum oxide, tungsten oxide, and niobium oxide; and the transition-metal foil wafer comprises any one of molybdenum foil, tungsten foil, and niobium foil.

10. The preparation method according to claim 5, wherein the substrate comprises any one of a SiO₂/Si substrate, an Al₂O₃ substrate, a fused silica substrate, a gold substrate, and a mica substrate with equally spaced holes, wherein
optionally, the substrate has a diameter of 1-450 mm.

11. The preparation method according to claim 5, wherein the supply source of chalcogenide elements comprises an elementary chalcogenide substance or a chalcogenide wafer, wherein
optionally, the elementary chalcogenide substance comprises any one of sulfur powder, selenium powder, and tellurium powder; and the chalcogenide wafer comprises a wafer made by pressing one or more of zinc sulfide, zinc selenide, zinc telluride, and tellurium oxide.

12. The preparation method according to claim 5, wherein the step S2 comprises: placing the combined growth module on a high-temperature resistant plate, and putting the combined growth module and the high-temperature resistant plate into a tubular container together; vacuumizing the tubular container until a gas pressure inside the container is 0.1-1 Pa; injecting an inert gas and maintaining pressure inside the container at 50-300 Pa; and heating to 500-1100° C. and preserving a temperature for 20-60 min, wherein
optionally, a heating rate is 20-100° C./min;
optionally, the high-temperature resistant plate comprises a quartz plate or an alumina plate;
optionally, the inert gas serves as a carrier gas at the same time; and
optionally, the inert gas comprises argon or nitrogen.

13. The preparation method according to claim 5, wherein the number of the growth modules stacked is 1-1000 in the step S2.

14. The preparation method according to claim 5, further comprising a pretreatment for the substrate before the step S1, wherein the pretreatment comprises any one of a plasma treatment, a potassium hydroxide solution treatment and a piranha solution treatment.

15. The preparation method according to claim 5, wherein after finishing the step S2, a heating process is turned off; a flow rate of a protective gas is maintained to be unchanged; and a system is cooled to a room temperature, so as to obtain wafer-scale transition-metal chalcogenides deposited on the growth base in batch quantity.

16. A transition-metal chalcogenide wafer prepared according to the preparation method according to claim 5.

17. The device according to claim 2, wherein three through holes are provided, wherein each of the three through holes is snapped therein with the slot assembly, and the three through holes are distributed triangularly.

18. The device according to claim 2, wherein a width of the first slot and a width of the second slot are the same or different; and a width of the third slot is larger than the width of the first slot, and/or the width of the third slot is larger than the width of the second slot.

19. The preparation method according to claim 6, wherein the number of the growth modules stacked is 1-1000 in the step S2.

20. The preparation method according to claim 6, further comprising a pretreatment for the substrate before the step S1, wherein the pretreatment comprises any one of a plasma treatment, a potassium hydroxide solution treatment and a piranha solution treatment.
